(19) United States
(12) Patent Application Publication
(10) Pub. No.: US 2026/0362667 A1
(43) Pub. Date: Nov. 12, 2026

(54) COMPLEMENTARY FIELD EFFECT TRANSISTOR (CFET) STRUCTURE AND METHOD OF MAKING

(71) Applicant: TAIWAN SEMICONDUCTOR MANUFACTURING COMPANY, LTD., Hsinchu (TW)

(72) Inventors: Hung-Li CHIANG, Hsinchu (TW); Wei-Cheng LIN, Hsinchu (TW); Jiann-Tyng TZENG, Hsinchu (TW)

(21) Appl. No.: 19/746,132

(22) Filed: Jul. 17, 2026

Related U.S. Application Data
(63) Continuation of application No. 19/098,117, filed on Apr. 2, 2025.
(60) Provisional application No. 63/701,259, filed on Sep. 30, 2024.

(51) Int. Cl. H10B 10/00; H10D 30/00; H10D 30/43; H10D 62/10; H10D 64/23; H10W 20/41; H10W 20/42; H10W 20/43

(52) U.S. Cl. CPC H10B 10/12; H10D 30/43; H10D 62/102; H10D 62/121; H10D 64/256; H10W 20/42; H10W 20/43; H10W 20/435; H10D 30/502

(57) ABSTRACT

A semiconductor device includes a first plurality of source/drain (S/D) regions configured to receive an input signal. The semiconductor device further includes a second plurality of S/D regions configured to output an output signal. The semiconductor device further includes a plurality of gate structures, each gate structure of the plurality of gate structures being between a corresponding S/D region of the first plurality of S/D regions and a corresponding S/D region of the second plurality of S/D regions, wherein each of the plurality of gate structures has a same dopant type. The semiconductor device further includes a dielectric material offset from each of the plurality of gate structures. The semiconductor device further includes a through via electrically connected to an S/D region of the second plurality of S/D regions, the through via extending through a substrate.

### PRIORITY CLAIM AND CROSS-REFERENCE

This application is a continuation of U.S. application Ser. No. 19/098,117, filed Apr. 2, 2025, which claims priority to U.S Provisional Application 63/701,259, filed Sep. 30, 2024, the entire contents of which are incorporated by reference.

### BACKGROUND

Complemental field effect transistor (CFET) structures are used in integrated circuits (ICs) in order to help to reduce the size of the ICs in comparison with other approaches. CFET structures include a first device having a first dopant type vertically displaced relative to a second device having a second dopant type opposite the first dopant type. The vertical displacement helps to reduce the overall size of the IC in comparison with horizontal displacement.

CFET structures are used in a variety of ICs, including memory, such as static random access memory (SRAM). In some instances, certain components of a memory cell use a single polarity. That is, the first device or the second device from a CFET structure is replaced with a dummy, not active, structure. The use of the dummy structure omits the functionality of one of the first device or the second device in the CFET structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an integrated circuit (IC), in accordance with some embodiments.

FIG. 2 is a perspective view of a complementary field effect transistor (CFET) structure, in accordance with some embodiments.

FIG. 3 is a cross-sectional view of a CFET structure, in accordance with some embodiments.

FIG. 4 is a cross-sectional view of a CFET structure, in accordance with some embodiments.

FIG. 5 is a cross-sectional view of a CFET structure, in accordance with some embodiments.

FIG. 6 is a cross-sectional view of a CFET structure, in accordance with some embodiments.

FIG. 7 is a cross-sectional view of a CFET structure, in accordance with some embodiments.

FIG. 8 is a cross-sectional view of a CFET structure, in accordance with some embodiments.

FIG. 9 is a cross-sectional view of a CFET structure, in accordance with some embodiments.

FIG. 10 is a cross-sectional view of a CFET structure, in accordance with some embodiments.

FIG. 11 is a cross-sectional view of a CFET structure, in accordance with some embodiments.

FIG. 12 is a cross-sectional view of a CFET structure, in accordance with some embodiments.

FIG. 13 is a cross-sectional view of a CFET structure, in accordance with some embodiments.

FIG. 14A is a top view of a CFET structure, in accordance with some embodiments.

FIG. 14B is a bottom view of a CFET structure, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Replacing one of the complementary functional devices of complementary field effect transistor (CFET) structures with a dummy structure is used to change a dual polarity of the CFET structure into a unipolar CFET structure. The unipolar CFET structure includes a single functional device in the vertical stack of the CFET structure. Stated differently, in a vertical direction of a single CFET structure there is only a p-type or an n-type functional device. The other of the p-type or n-type device is replaced by a dummy structure. This dummy structure replacement causes the CFET structure to experience high parasitic capacitance. The high parasitic capacitance increases lag time within an integrated circuit (IC) and power consumption of the IC.

Other options for converting the dual polarity of the CFET structure to a unipolar CFET structure include including of additional gate isolation structures or changing a polarity of one of the vertically stacked devices of the CFET structure. Each of these options includes additional processing steps that are time consuming and potentially increase the overall size of the IC.

In order to convert a dual polarity CFET structure into a unipolar CFET structure according to some aspects of this description, a gate structure of one of the stacked devices of the CFET structure is removed and a dielectric material is deposited into the opening defined by the removal of the stacked device. Replacing the gate structure of one of the stacked devices with a dielectric material reduces parasitic capacitance within the unipolar CFET structure in comparison with the use of a dummy device. In addition, the processing steps implemented to remove the gate structure and deposit the dielectric material have reduced complexity and lower cost in comparison with including additional isolation structures or changing the polarity of one of the vertically stacked devices.

In some embodiments, the removal of the gate structure is performed using a series of photolithography and etching steps to define an opening within the CFET structure. A dielectric material is then deposited into the defined opening. In some embodiments, a planarization process is performed on the deposited dielectric material to facilitate formation of an interconnect structure or other suitable IC component.

The following description includes examples of devices of certain dopant types being replaced with dielectric materials. One of ordinary skill in the art would recognize that the specific dopant types mentioned are mere examples and are not intended to limit the scope of this disclosure. One of ordinary skill in the art would recognize that the dopant type of the replaced structure will depend on a design of the IC that includes the unipolar CFET structure. For example, in some embodiments, a power gating header will replace n-type devices with the dielectric material, while a power gating footer will replace p-type devices with the dielectric material. One of ordinary skill in the art would recognize other examples are within the scope of this description. One of ordinary skill in the art would further understand that a combination of source/drain (S/D) regions and gate structure are usable to define a transistor.

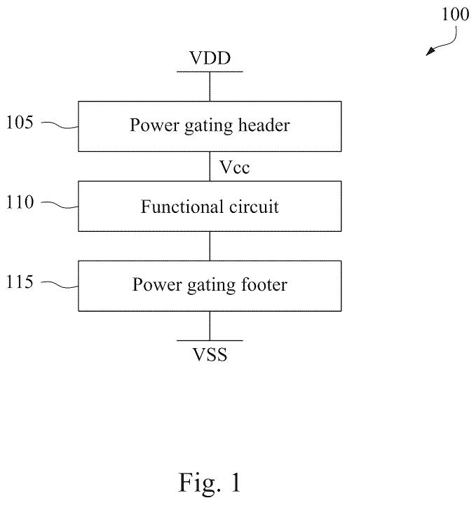

FIG. 1 is a block diagram of an IC 100, in accordance with some embodiments. The IC 100 includes a power gating header 105 configured to receive a supply voltage VDD. The power gating header 105 is capable of electrically separating a functional circuit 110 from the supply voltage VDD, effectively turning OFF the functional circuit 110. In some embodiments, the power gating header 105 converts the supply voltage VDD to an operating voltage VCC which is supplied to the functional circuit 110. A power gating footer 115 is electrically between the functional circuit 110 and a ground voltage VSS. The power gating footer 115 is usable to electrically separate the functional circuit 110 from the ground voltage VSS, effectively turning OFF the functional circuit 110. In some embodiments, the IC omits either the power gating header 105 or the power gating footer 115.

In some embodiments, the power gating header 105 is a unipolar CFET structure. The unipolar CFET structure includes functional devices of a single dopant type. In some embodiments, for the power gating header 105 the n-type devices are replaced with dielectric material. By including a unipolar CFET structure with selected dopant type devices replaced by dielectric material in the power gating header 105, the power gating header 105 reduces power consumption and improves IC speed in comparison with other approaches. As noted above, in some embodiments, the power gating header 105 is omitted from the IC 100 and only the power gating footer 115 is used to turn the functional circuit 110 ON or OFF.

In some embodiments, the power gating footer 115 is a unipolar CFET structure. The unipolar CFET structure includes functional devices of a single dopant type. In some embodiments, for the power gating footer 115 the p-type devices are replaced with dielectric material. By including a unipolar CFET structure with selected dopant type devices replaced by dielectric material in the power gating footer 115, the power gating footer 115 reduces power consumption and improves IC speed in comparison with other approaches. As noted above, in some embodiments, the power gating footer 115 is omitted from the IC 100 and only the power gating header 105 is used to turn the functional circuit 110 ON or OFF.

In some embodiments, the functional circuit 110 includes a unipolar CFET structure. In some embodiments, the functional circuit 110 includes at least one CFET structure with dual polarity and at least one unipolar CFET structure. In some embodiments, the functional circuit includes a memory device, such as a static random access memory (SRAM) cell. One of ordinary skill in the art would understand that other types of functional circuit are within the scope of this description.

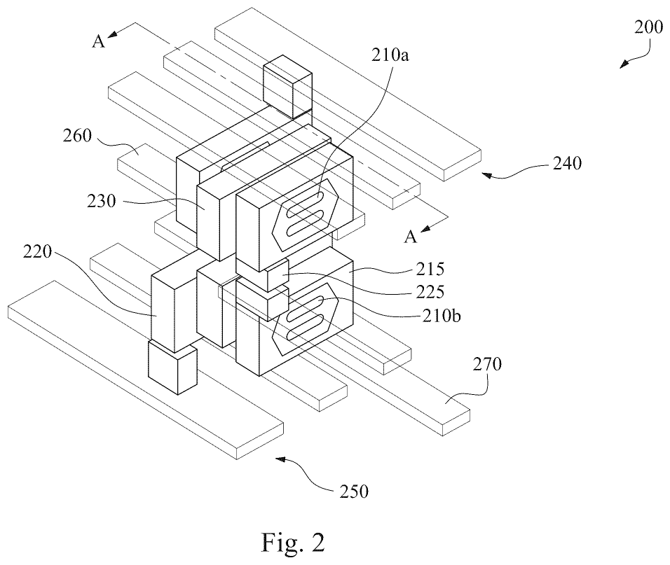

FIG. 2 is a perspective view of a CFET structure 200, in accordance with some embodiments. Not all aspects of the CFET structure 200 are labeled for clarity of the drawing. The CFET structure 200 is a dual polarity CFET structure 200. The CFET structure 200 includes vertically stacked devices. Each of the vertically stacked devices is a gate all around (GAA) transistor. An upper device of the CFET structure 200 includes a first set of nanowires 210a. The first set of nanowires 210a has a first dopant type, e.g., p-type dopant. A lower device of the CFET structure 200 includes a second set of nanowires 210b. The second set of nanowires 210b has a second dopant type, e.g., n-type dopant, opposite to the first dopant type. One of ordinary skill in the art would recognize that while the CFET structure 200 includes multiple nanowires in each of the upper device and the lower device, a CFET structure 200 having a single nanowire in at least one of the upper device or the lower device is within the scope of this description. The CFET structure 200 further includes a source/drain (S/D) electrode 215 around a first S/D region of each of the upper device and the lower device. For the sake of clarity of the drawing, only the S/D electrode 215 for the lower device is labeled in FIG. 2. The CFET structure further includes a gate electrode 230 surrounding a channel region of each of the upper device and the lower device. For the sake of clarity of the drawing, only the gate electrode 230 for the upper device is labeled in FIG. 2. The CFET structure 200 further includes a second S/D electrode 220 around a second S/D region of each of the upper device and the lower device. For the sake of clarity of the drawing, only the S/D electrode 220 for the lower device is labeled in FIG. 2. The CFET structure 200 further includes a via 225 electrically connecting the first S/D electrode 215 for the lower device to the first S/D electrode for the upper device. While the via 225 is used for electrical connection between the first S/D electrode 215, one of ordinary skill in the art would understand that in some embodiments the CFET structure 200 omits the via 225 and includes a via electrically connecting the gate electrode 230 or the second S/D electrode 220.

The CFET structure 200 is electrically connected to interconnect structures on both a top side and a bottom side. A top interconnect structure 240 provides electrical connection to the upper device of the CFET structure 200. A bottom interconnect structure 250 provides electrical connection to the lower device of the CFET structure 200. The CFET structure 200 includes vias (shown but not labeled) electrically connecting the CFET structure 200 to each of the top interconnect structure 240 and the bottom interconnect structure 250. By separating the top interconnect structure 240 from the bottom interconnect structure 250 in the vertical direction, an overall size of the CFET structure 200 is reduced and signal routing is simplified in comparison with other approaches using structures other than the CFET structure 200.

An input conductive line 260 is electrically connected to the second S/D electrode of the upper device of the CFET structure 200. The electrical connection between the input conductive line 260 and the second S/D electrode of the upper device is obscured by the gate electrode 230 of the upper device in FIG. 2. An output conductive line 270 is electrically connected to the via 225 for electrical connection to the first S/D electrode for the upper device of the CFET structure 200. In some embodiments, the output conductive line 270 is electrically connected directly to the first S/D electrode of the upper device instead of electrically connecting to the first S/D electrode of the upper device through the via 225.

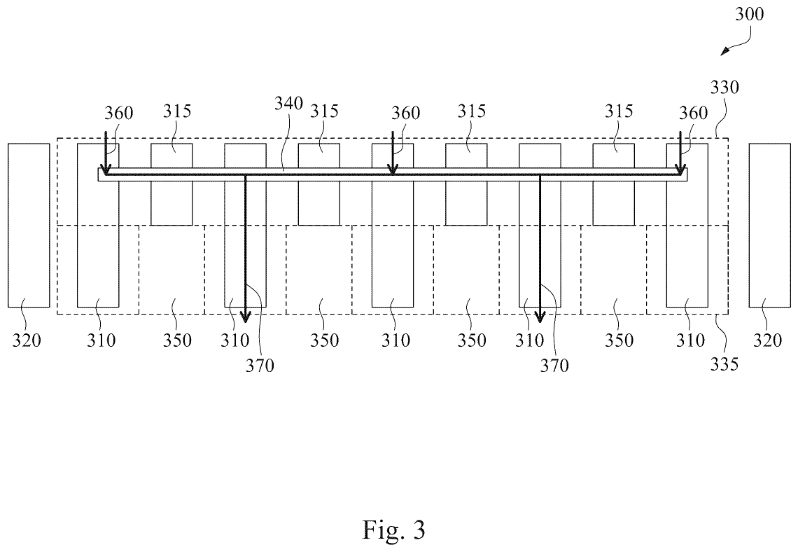

FIG. 3 is a cross-sectional view of a CFET structure 300, in accordance with some embodiments. The CFET structure 300 is a unipolar CFET structure. The CFET structure 300 is for a multi-finger device. A multi-finger device includes a plurality of nanowires (or groups of nanowires) extending parallel and separated from one another in a horizontal direction. The gates electrodes of each nanowire (or group of nanowires) are electrically connected together so that each of the transistors is activated by a single signal. A multi-finger device provides a plurality of paths for current to flow within the CFET structure 300, which reduces resistance in comparison with a single finger device. In some embodiments, the CFET structure 300 is a view taken along line A-A of CFET structure 200 (FIG. 2), which is modified to have multiple fingers.

The CFET structure 300 includes an upper device 330 and a lower device 335. While the terms upper device 330 and lower device 335 are used for clarity of explaining the structure in FIG. 3, one of ordinary skill in the art would understand that in a real world product the upper device 330 and the lower device 335 are flipped, i.e., rotated 180-degrees, in some embodiments.

The CFET structure 300 includes a plurality of S/D regions 310. The S/D regions 310 are shown as continuous between the upper device 330 and the lower device 335. This indicates that S/D contacts of the S/D regions 310 are electrically connected in the vertical direction. Between adjacent S/D regions 310 in the upper device 330, the CFET structure 300 includes gate structures 315. The gate structures 315 are electrically connected using conductive line 340. The conductive line 340 is used to activate all gate structure 315 together. The CFET structure 300 further includes continuous poly on oxide definition edge (CPODE) structures 320 on each end of the CFET structure 300. The CPODE structures 320 help to provide isolation for the active components of the CFET structure 300 and help to reduce the size of an IC.

The CFET structure 300 includes a plurality of inputs 360 and a plurality of outputs 370. The inputs 360 are at the upper device 330 and the outputs 370 are at the lower device 335. The inputs 360 and outputs 370 are on alternating S/D regions 310, i.e., no single S/D region 310 has both an input 360 and an output 370. During operation, when a gate structure 315 is activated by a signal received from the conductive line 340, an input 360 from a first S/D region 310 is transferred through a channel controlled by the gate structure 315 to be output 370 by a second S/D region 310.

In contrast, to the upper device 330, the lower device 335 is free of gate structures 315. In place of gate structures 315, the lower device 335 includes a plurality of openings 350, which are able to be filled with a dielectric material (not shown in FIG. 3).

In order to form the CFET structure 300, a dual polarity CFET structure is initially formed. Prior to forming an interconnect structure on a peripheral side of the lower device 335 of the dual polarity CFET structure, a mask is formed along the peripheral side of the lower device 335. The mask exposes the gate structures 315 of the lower device 335. A series of photolithography and etching processes are used to remove the gate structures 315 from the lower device 335 to define a plurality of openings. The mask is then removed from the lower device 335 and a dielectric material is deposited into the plurality of openings. In some embodiments, the dielectric material includes silicon oxide, silicon nitride, silicon oxynitride, silicon carbide, silicon oxycarbide, combinations thereof, or other suitable dielectric materials. In some embodiments, the deposition process includes chemical vapor deposition (CVD), atomic layer deposition (ALD), or another suitable deposition process. In some embodiments, a planarization process, such a chemical mechanical planarization (CMP), is performed following deposition of the dielectric material to remove the dielectric material outside of the openings.

The replacement of the gate structures 315 from the lower device 335 with a dielectric material removes the gate structures having the second polarity. Thus, the replacement of the gate structures 315 from the lower device 335 with a dielectric material changes a dual polarity CFET structure, such as CFET structure 200 (FIG. 2), to a unipolar CFET structure 300. In a dual polarity CFET structure that includes dummy components for the lower device, the gate structures would remain, but the gate structures would not be connected to incoming signals. The presence of the conductive gate structures in the dummy components would increase the parasitic capacitance of the dual polarity CFET structure in comparison to the CFET structure 300, which is unipolar. As a result, the CFET structure 300 has lower power consumption and reduced lag time in comparison with the CFET structure including the dummy components.

In another approach for utilizing only the upper device gate structures, a large isolation structure is formed between the gate structures of the upper device and the gate structures of the lower device. This process increases production time and expense as well as increases a size of the CFET structure in comparison with the replacement of the gate structure of the lower device 335 with the dielectric material, as in CFET structure 300.

Another approach for forming a unipolar CFET structure includes doping the gate structures of the lower device with a sufficient amount of dopants to change the dopant type of the gate structures from the second dopant type to the first dopant type. This process increases production time and expense in comparison with the replacement of the gate structures of the lower device 335 with the dielectric material, as in CFET structure 300.

In some embodiments, the CFET structure 300 is usable to form the power gating header 105 (FIG. 1). In some embodiments where the CFET structure 300 is usable to form the power gating header 105 (FIG. 1), the upper device 330 includes p-type gate structures; and the n-type gate structures of the lower device 335 are replaced with the dielectric material. In some embodiments, the CFET structure 300 is usable to form the power gating footer 115 (FIG. 1). In some embodiments where the CFET structure 300 is usable to form the power gating footer 115 (FIG. 1), the upper device 330 includes n-type gate structures; and the p-type gate structures of the lower device 335 are replaced with the dielectric material. As noted above, an orientation of the CFET structure 300 is reversible, i.e., the structure is rotated 180-degrees.

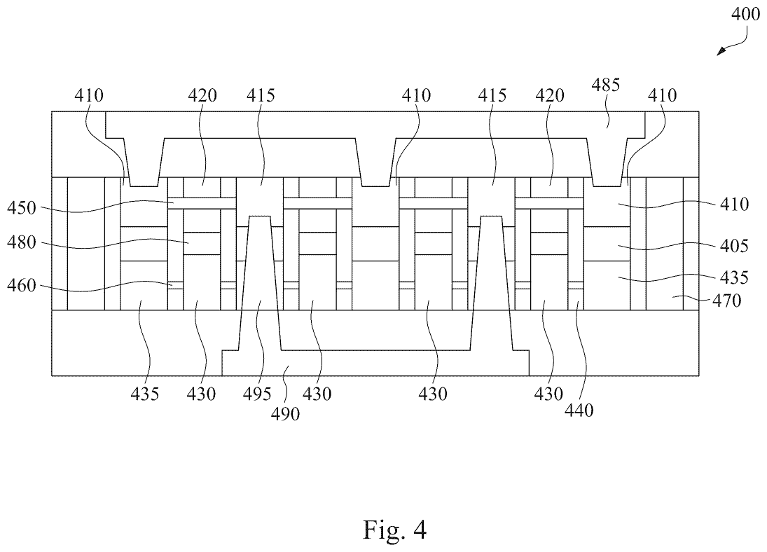

FIG. 4 is a cross-sectional view of a CFET structure 400, in accordance with some embodiments. The CFET structure 400 is a unipolar CFET structure. The CFET structure 400 is a multi-finger device. In some embodiments, the CFET structure 400 is similar to the CFET structure 300 in that the gate structures of the lower device are replaced with dielectric material. In some embodiments, the CFET structure 400 is formed in a manner similar to that described above with respect to the CFET structure 300 (FIG. 3), and a detailed description of some formation aspects of the CFET structure 400 is omitted for the sake of brevity.

The CFET structure 400 includes a first plurality of S/D regions 410, the first plurality of S/D regions 410 is configured to receive an input signal, e.g., from input 260 (FIG. 2), from a top interconnect structure 485. The CFET structure 400 further includes a second plurality of S/D regions 415, the second plurality of S/D regions 415 is configured to output an output signal, e.g., to output 270 (FIG. 2), to a bottom interconnect structure 490. The CFET structure 400 further includes a plurality of gate structures 420. Each gate structure 420 of the plurality of gate structures 420 is between a corresponding S/D region 410 of the first plurality of S/D regions 410 and a corresponding S/D region 415 of the second plurality of S/D regions 415. The plurality of gate structures 420 all have a same dopant type, e.g., p-type or n-type.

The CFET structure 400 further includes a third plurality of S/D regions 435. Each S/D region 435 of the third plurality of S/D regions 435 is vertically offset from a corresponding S/D region of the first plurality of S/D regions 410 or the second plurality of S/D regions 415. A portion of a substrate 405 is between corresponding S/D regions 435 of the third plurality of S/D regions 435 and a corresponding S/D region 410 of the first plurality of S/D regions 410 or a corresponding S/D region 415 of the second plurality of S/D regions 415.

The CFET structure 400 further includes a dielectric material 430 vertically offset from each of the plurality of gate structures 420. The dielectric material 430 is located where gate structures of a lower device of the CFET structure 400 were replaced.

The CFET structure 400 includes a plurality of spacers 440. Each of the plurality of spacers 440 extends continuously along sidewalls of the plurality of gate structure 420 and along sidewalls of the dielectric material 430. In some embodiments, a portion of the spacers 440 along sidewalls of the dielectric material 430 are omitted due to removal of the portion of the spacers 440 during replacement of the gate structures during formation of the dielectric material 430. In such a structure, the dielectric material 430 directly contacts adjacent S/D regions 435 of the third plurality of S/D regions 435, in some embodiments. The CFET structure 400 includes spacers 440 having a uniform width in a horizontal direction. In some embodiments, the spacers 440 have a variable width, e.g., a curved sidewall on a side distal from the plurality of gate structures 420.

The CFET structure 400 further includes a channel region 450 to be selectively controlled based on a signal received by each of the plurality of gate structures 420. The channel region 450 is continuous through each of the plurality of gate structures 420. The channel region 450 extends partially into the CPODE 470 on each side of the CFET structure 400. In some embodiments, the channel region 450 does not into the CPODE 470 on at least one side of the CFET structure 400. The channel region 450 is discontinuous through the first plurality of S/D regions 410 and the second plurality of S/D regions 415. In some embodiments, the channel region 450 includes silicon. In some embodiments, the channel region 450 has a first dopant type, such a p-type dopant or n-type dopant.

The CFET structure 400 further includes a channel region 460. The channel region 460 is discontinuous at each of the dielectric material 430 and the third plurality of S/D regions 435. The channel region 460 extends partially into the CPODE 470 on each side of the CFET structure 400. In some embodiments, the channel region 460 does not extend into the CPODE 470 on at least one side of the CFET structure 400. In some embodiments, the channel region 460 includes silicon. In some embodiments, the channel region 450 has a second dopant type, such a p-type dopant or n-type dopant, where the second dopant type is opposite to the first dopant type of the channel region 450.

The CPODE 470 includes spacers 440 along sidewalls of the CPODE 470. In some embodiments, the spacers 440 along the sidewalls of the CPODE 470 are completely omitted. In some embodiments, the spacers 440 along the sidewalls of the CPODE 470 adjacent to the third plurality of S/D regions 435 are omitted.

The CFET structure 400 further includes a middle dielectric isolation (MDI) layer 480 between corresponding gate structures 420 of the plurality of gate structures 420 and the dielectric material 430. In some embodiments, the MDI layer 480 includes a same composition as the dielectric material 430. In some embodiments, the MDI layer 480 includes a different composition from the dielectric material 430. In some embodiments, the MDI layer 480 is removed during the replacement of the gate structures of the lower device of the CFET structure 400 during formation of the dielectric material 430, such that the dielectric material 430 directly contacts the plurality of gate structures 420.

The CFET structure 400 further includes a plurality of through vias 495 electrically connecting the bottom interconnect structure 490 to the second plurality of S/D regions 415. Each of the through vias 495 extends through a corresponding S/D region 435 of the third plurality of S/D regions 435 and through the portion of the substrate 405 to electrically connect to a corresponding S/D region 415 of the second plurality of S/D regions 415. The CFET structure 400 includes through vias 495 having a tapered profile. In some embodiments, the through vias have parallel sidewalls.

According to some embodiment, the substrate 405 is a semiconductor substrate. In some embodiments, the substrate 405 includes a single crystalline semiconductor layer on at least the surface of the substrate 405. In some embodiments, the substrate 405 includes a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 405 is made of Si. In some embodiments, the substrate 405 is a silicon-on-insulator (SOI) substrate, which includes an insulating layer (not shown) disposed between two silicon layers. In some embodiments, the insulating layer is an oxide.

In some embodiments, one or more buffer layers (not shown) are formed on the surface of the substrate 405. The buffer layers serve to gradually change a lattice constant from that of the substrate to that of the source/drain (S/D) regions to be grown on the substrate 405. In some embodiments, the buffer layers are formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, and InP. In some embodiments, the substrate 405 includes SiGe buffer layers epitaxially grown on a silicon substrate. In some embodiments, the germanium concentration of the SiGe buffer layers increases from about 30 atomic percent germanium for the bottom-most buffer layer to about 70 atomic percent germanium for the top-most buffer layer. In some embodiments, the substrate 405 includes various regions that have been suitably doped with impurities (e.g., p-type or n-type impurities). The dopants are, for example boron for a p-type field effect transistor FET (PFET) and phosphorus for an n-type FET (NFET).

The first plurality of S/D regions 410, the second plurality of S/D regions 415 and the third plurality of S/D regions 435 are formed using similar processes. The S/D regions are epitaxially grown. In some embodiments, the epitaxially grown S/D regions include one or more layers of Si, SiP, SiC and SiCP for n-channel FETs or Si, SiGe, Ge for p-channel FETs. For p-channel FETs, p-type dopants, such as boron (B), are also included in the epitaxial S/D regions. In some embodiments, the epitaxial S/D regions include one or more layers of Si, SiGe, and Ge for a p-channel FET. In some embodiments, the epitaxial S/D regions are formed by an epitaxial growth method using CVD, ALD, molecular beam epitaxy (MBE), or another suitable epitaxial process. In some embodiments, the epitaxial S/D regions grow both vertically and horizontally to form facets, which correspond to crystalline planes of the material used for the substrate 405.

The plurality of gate structures 420 are formed surrounding the channel region 460, also called nanowire or nanostructure, of the CFET structure 400. In some embodiments, the plurality of gate structures 420 include a conformal metal layer on a high-k dielectric layer, where the high-k dielectric layer is between the metal layer and the nanowires. In some embodiments, the metal layer includes Al, TiAl, TiAlₓ, TiAlCₓ, TiCₓ, TaCₓ, or a composite of any of these materials. In some embodiments, the metal layer is formed by suitable deposition processes such as ALD or other suitable deposition processes.

The dielectric material 430 replaces gate structures in the lower device of the CFET structure 400. In some embodiments, the dielectric material 430 includes silicon oxide, silicon nitride, silicon oxynitride, or another suitable dielectric material. In some embodiments, the dielectric material is formed by CVD, ALD, or another suitable deposition method.

The spacers 440 are on sidewalls of the plurality of gate structures 420 and the dielectric material 430. In some embodiments, spacers 440 include nitride-containing layer such as Si₃N₄ layer formed by flowable CVD, ALD, or other suitable deposition processes. In some embodiments, the spacers 440 are formed by first forming a conformal layer on the sidewalls, followed by an anisotropic etch process to remove portions of the conformal layer formed on horizontal surfaces, leaving the spacers 440 formed on vertical surfaces. In some embodiments, a portion of the spacers 440 formed on the sidewalls of the plurality of gate structures 420 and the dielectric material 430 are recessed or removed by the anisotropic etch process. The spacers 440 also extend along sidewalls of the MD layer 480. In some embodiments, the spacers 440 below the MDI layer 480 are removed by an etching process used to remove the gate structures of the lower device of the CFET structure 400.

The channel region 450 and the channel region 460 are formed by depositing a semiconductor material during formation of the upper device and the lower device, respectively. In some embodiments, the channel region 450 includes a same material as the channel region 460. In some embodiments, the channel region 450 includes a different material from the channel region 460. Portions of the channel region 460 are removed during the formation of the dielectric material 430. In some embodiments, portions of the channel region 460 extend into spacers 440.

In some embodiments, the MDI layer 480 includes silicon oxide SiO₂ formed by thermal oxidation or suitable deposition processes. In some embodiments, the MDI layer 480 has a thickness about 1.5 to about 3 times thicker than a nanowire of the CFET structure 400.

The top interconnect structure 485 and the bottom interconnect structure 490 provide electrical connections to the CFET structure 400 from both a top side and a bottom side of the CFET structure 400. The top interconnect structure 485 and the bottom interconnect structure 490 independently include a series of dielectric layers with conductive components formed therein to route electrical signals in accordance with a designed function of the CFET structure 400.

The through vias 495 provides electrical connection between the bottom interconnect structure 490 and the second plurality of S/D regions 415. The through vias are formed by a series of etching processes to define an opening extending through the corresponding S/D regions 435 of the third plurality of S/D regions 435 and through the substrate 405. In some embodiments, the openings extend into the second plurality of S/D regions 415. In some embodiments, the openings land on the second plurality of S/D regions 415. A conductive material is deposited into the openings to provide an electrical connection to the second plurality of S/D regions 415. In some embodiments, the conductive material includes W, Al, Cu, Co, or another suitable conductive material. In some embodiments, a liner layer is deposited prior to the conductive material to separate the conductive material from the surrounding components of the CFET structure 400. The liner layer helps to prevent diffusion of the conductive material into the surrounding components of the CFET structure 400.

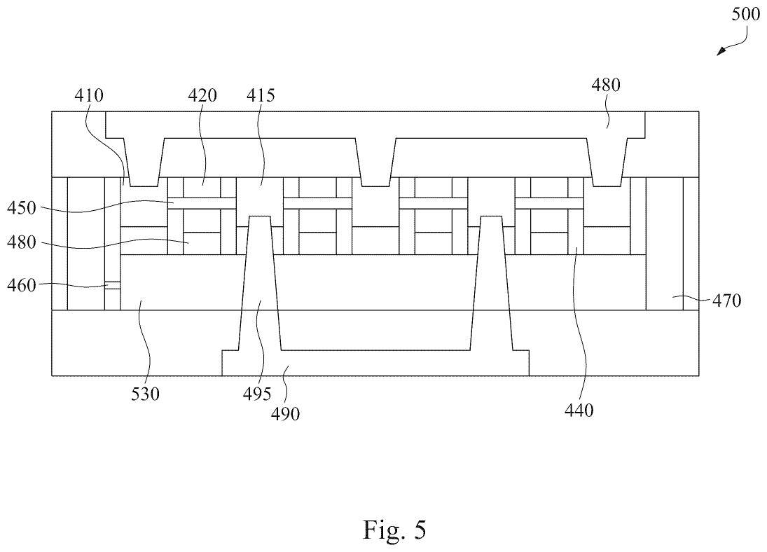

FIG. 5 is a cross-sectional view of a CFET structure 500, in accordance with some embodiments. The CFET structure 500 is a unipolar CFET structure. The CFET structure 500 is a multi-finger device. In some embodiments, the CFET structure 500 is similar to the CFET structure 400 (FIG. 4) and similar elements have a same reference number. Labeling of components, such as less than all of the plurality of gate structures 420 (FIG. 4) and a detailed description of some aspects of the CFET structure 500 is omitted for the sake of brevity and clarity of the drawing.

In comparison with the CFET structure 400 (FIG. 4), the CFET structure 500 includes a dielectric material 530 replacing an entirety of the lower device. The dielectric material 530 extends from the CPODE 470 on a first side of the CFET structure 500 to the CPODE 470 on a second side of the CFET structure 500. The components of the lower device are removed using a series of etching processes. In some embodiments, the etching processes remove at least a portion of the spacers 440 along sidewalls of the CPODE 470. In some embodiments, the etching processes do not remove the spacers 440 along the sidewalls of the CPODE 470. The CFET structure 500 includes the dielectric material 530 contacting the MDI layer 480 and the substrate 405. In some embodiments, the MDI layer 480 and the substrate 405 are removed and the dielectric material 530 extends to directly contact the first plurality of S/D regions 410 and the second plurality of S/D regions 415. In some embodiments, the dielectric material 530 includes a similar material as the dielectric material 430 (FIG. 4). In some embodiments, the dielectric material 530 is formed in a manner similar to the dielectric material 430 (FIG. 4).

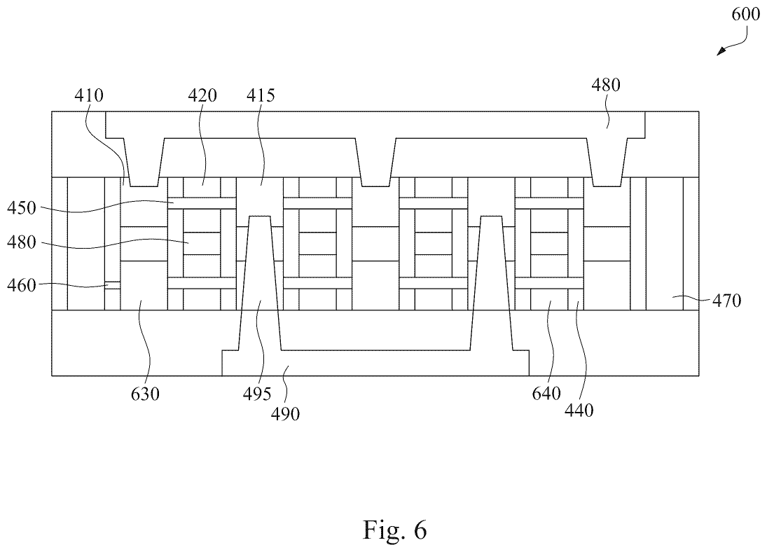

FIG. 6 is a cross-sectional view of a CFET structure 600, in accordance with some embodiments. The CFET structure 600 is a unipolar CFET structure. The CFET structure 600 is a multi-finger device. In some embodiments, the CFET structure 600 is similar to the CFET structure 400 (FIG. 4) and similar elements have a same reference number. Labeling of components, such as less than all of the plurality of gate structures 420 (FIG. 4) and a detailed description of some aspects of the CFET structure 600 is omitted for the sake of brevity and clarity of the drawing.

In comparison with the CFET structure 400 (FIG. 4), the CFET structure 600 includes a dielectric material 630 replacing the third plurality of S/D regions 435 (FIG. 4). In addition, the CFET structure 600 includes a second plurality of gate structures 640 in the lower device. The nanowires associated with the second plurality of gate structures 640 have an opposite dopant type from the nanowires associated with the plurality of gate structures 420. The channel region 460 extends through the second plurality of gate structures 640, but the channel region 460 is discontinuous within the dielectric material 630. A series of etching processes is used to remove the third plurality of S/D regions 435 (FIG. 4) to define a plurality of openings. The dielectric material 630 is deposited into the openings. The CFET structure 600 includes the dielectric material 630 contacting the substrate 405. In some embodiments, the substrate 405 is removed and the dielectric material 630 extends to directly contact the first plurality of S/D regions 410 and the second plurality of S/D regions 415. The through vias 495 extend through the dielectric material 630 to electrically connect to the second plurality of S/D regions 415. In some embodiments, the dielectric material 630 includes a similar material as the dielectric material 430 (FIG. 4). In some embodiments, the dielectric material 630 is formed in a manner similar to the dielectric material 430 (FIG. 4).

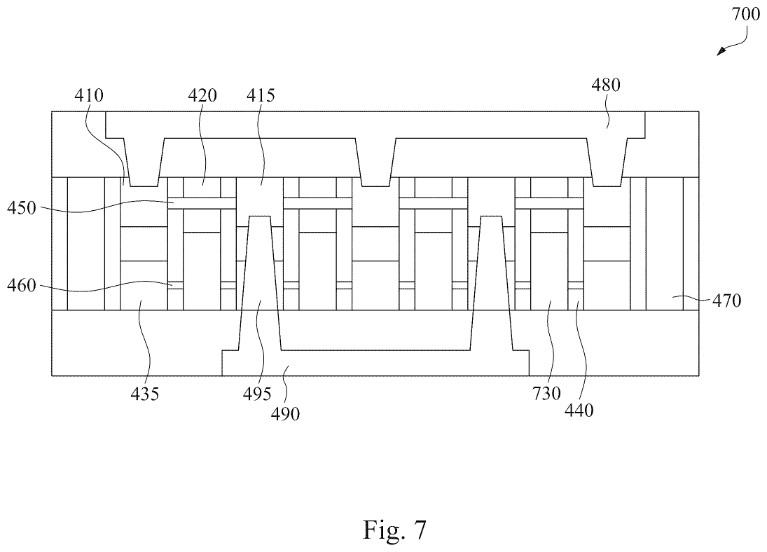

FIG. 7 is a cross-sectional view of a CFET structure 700, in accordance with some embodiments. The CFET structure 700 is a unipolar CFET structure. The CFET structure 700 is a multi-finger device. In some embodiments, the CFET structure 700 is similar to the CFET structure 400 (FIG. 4) and similar elements have a same reference number. Labeling of components, such as less than all of the plurality of gate structures 420 (FIG. 4) and a detailed description of some aspects of the CFET structure 700 is omitted for the sake of brevity and clarity of the drawing.

In comparison with the CFET structure 400 (FIG. 4), the CFET structure 700 includes a dielectric material 730 in direct contact with the plurality of gate structures 420. The CFET structure 700 includes the dielectric material 730 replacing the MDI layer 480. In some embodiments, during formation of a dual polarity CFET structure as an intermediate step to forming the CFET structure 700 the MDI layer 480 is omitted. In some embodiments, the dielectric material 730 includes a similar material as the dielectric material 430 (FIG. 4). In some embodiments, the dielectric material 730 is formed in a manner similar to the dielectric material 430 (FIG. 4).

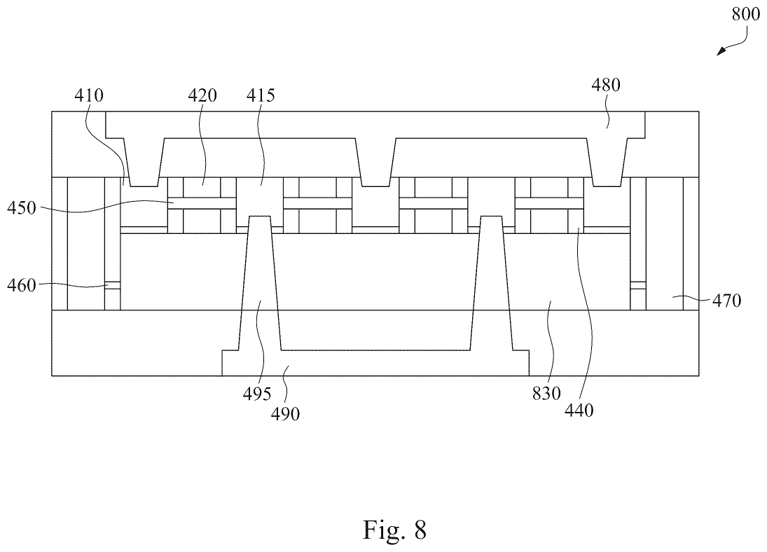

FIG. 8 is a cross-sectional view of a CFET structure 800, in accordance with some embodiments. The CFET structure 800 is a unipolar CFET structure. The CFET structure 800 is a multi-finger device. In some embodiments, the CFET structure 800 is similar to the CFET structure 400 (FIG. 4) and similar elements have a same reference number. Labeling of components, such as less than all of the plurality of gate structures 420 (FIG. 4) and a detailed description of some aspects of the CFET structure 800 is omitted for the sake of brevity and clarity of the drawing.

In comparison with the CFET structure 400 (FIG. 4), the CFET structure 800 includes a dielectric material 830 replacing an entirety of the lower device. The dielectric material 830 extends from the CPODE 470 on a first side of the CFET structure 800 to the CPODE 470 on a second side of the CFET structure 800. The components of the lower device are removed using a series of etching processes. In some embodiments, the etching processes remove at least a portion of the spacers 440 along sidewalls of the CPODE 470. In some embodiments, the etching processes do not remove the spacers 440 along the sidewalls of the CPODE 470. The CFET structure 800 includes the dielectric material 830 contacting the plurality of gate structures 420 and the substrate 405. In some embodiments, the substrate 405 is removed and the dielectric material 830 extends to directly contact the first plurality of S/D regions 410 and the second plurality of S/D regions 415. In some embodiments, the dielectric material 830 includes a similar material as the dielectric material 430 (FIG. 4). In some embodiments, the dielectric material 830 is formed in a manner similar to the dielectric material 430 (FIG. 4).

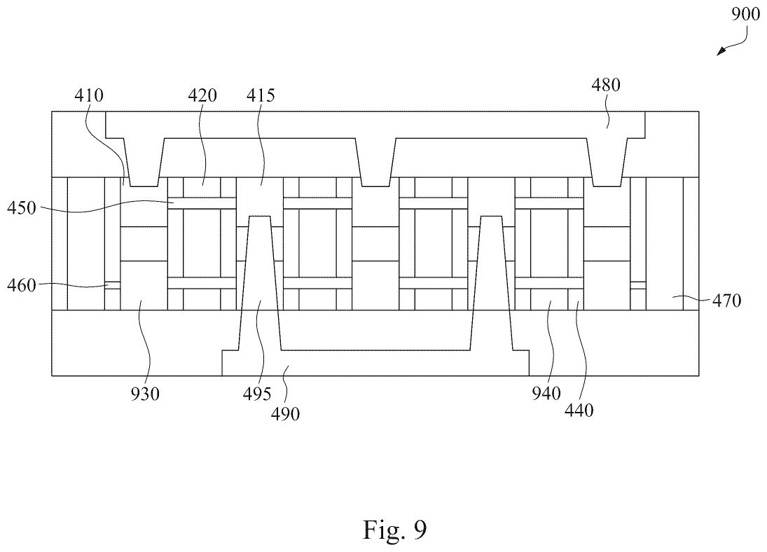

FIG. 9 is a cross-sectional view of a CFET structure 900, in accordance with some embodiments. The CFET structure 900 is a unipolar CFET structure. The CFET structure 900 is a multi-finger device. In some embodiments, the CFET structure 900 is similar to the CFET structure 400 (FIG. 4) and similar elements have a same reference number. Labeling of components, such as less than all of the plurality of gate structures 420 (FIG. 4) and a detailed description of some aspects of the CFET structure 900 is omitted for the sake of brevity and clarity of the drawing.

In comparison with the CFET structure 400 (FIG. 4), the CFET structure 900 includes a dielectric material 930 replacing the third plurality of S/D regions 435 (FIG. 4). In addition, the CFET structure 900 includes a second plurality of gate structures 940 in the lower device which directly contact the plurality of gate structures 420 in the upper device. The nanowires associated with the second plurality of gate structures 640 have an opposite dopant type from the nanowires associated with the plurality of gate structures 420. The channel region 460 extends through the second plurality of gate structures 940, but the channel region 460 is discontinuous within the dielectric material 930. A series of etching processes is used to remove the third plurality of S/D regions 435 (FIG. 4) to define a plurality of openings. The dielectric material 930 is deposited into the openings. The CFET structure 900 includes the dielectric material 930 contacting the substrate 405. In some embodiments, the substrate 405 is removed and the dielectric material 930 extends to directly contact the first plurality of S/D regions 410 and the second plurality of S/D regions 415. The through vias 495 extends through the dielectric material 930 to electrically connect to the second plurality of S/D regions 415. In some embodiments, the dielectric material 930 includes a similar material as the dielectric material 430 (FIG. 4). In some embodiments, the dielectric material 930 is formed in a manner similar to the dielectric material 430 (FIG. 4).

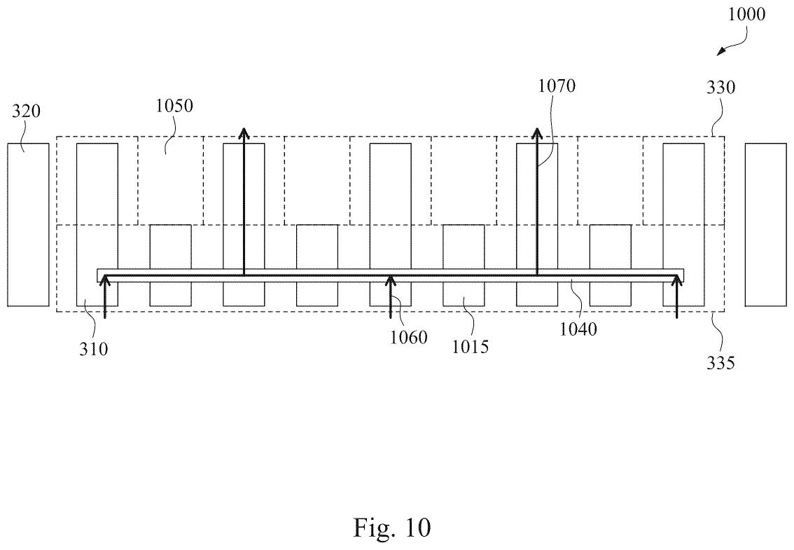

FIG. 10 is a cross-sectional view of a CFET structure 1000, in accordance with some embodiments. The CFET structure 1000 is a unipolar CFET structure. The CFET structure 1000 is a multi-finger device. In some embodiments, the CFET structure 1000 is similar to the CFET structure 300 (FIG. 3) and similar elements have a same reference number. Labeling of components, such as less than all of the S/D regions 310 (FIG. 3) and a detailed description of some aspects of the CFET structure 1000 is omitted for the sake of brevity and clarity of the drawing.

In comparison with the CFET structure 300 (FIG. 3), the CFET structure 1000 replaces the gate structures in the upper device 330 instead of in the lower device 335. A dielectric material is deposited into the openings 1050 defined by removing the gate structures in the upper device 330. The CFET structure 1000 includes a plurality of inputs 1060 and a plurality of outputs 1070. The inputs 1060 are at the lower device 335 and the outputs 1070 are at the upper device 330. The inputs 1060 and outputs 1070 are on alternating S/D regions 310, i.e., no single S/D region 310 has both an input 1060 and an output 1070. During operation, when a gate structure 1050 is activated by a signal received from the conductive line 1040, an input 1060 from a first S/D region 310 is transferred through a channel controlled by the gate structure 1015 to be output 1070 by a second S/D region 310. In some embodiments, the CFET structure 1000 is formed in a similar manner as CFET structure 300 (FIG. 3) with the replacement process being performed on the upper device instead of on the lower device.

In some embodiments, the CFET structure 1000 is usable to form the power gating header 105 (FIG. 1). In some embodiments where the CFET structure 1000 is usable to form the power gating header 105 (FIG. 1), the upper device 330 includes p-type gate structures; and the n-type gate structures of the lower device 335 are replaced with the dielectric material. In some embodiments, the CFET structure 1000 is usable to form the power gating footer 115 (FIG. 1). In some embodiments where the CFET structure 1000 is usable to form the power gating footer 115 (FIG. 1), the upper device 330 includes n-type gate structures; and the p-type gate structures of the lower device 335 are replaced with the dielectric material. In some embodiments, an orientation of the CFET structure 1000 is reversible, i.e., the structure is rotated 180-degrees.

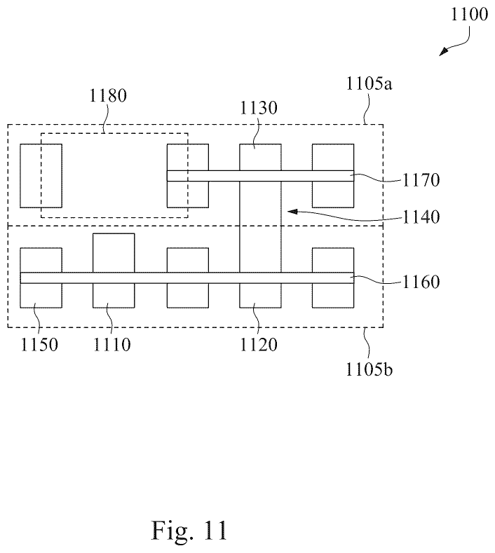

FIG. 11 is a cross-sectional view of a CFET structure 1100, in accordance with some embodiments. The CFET structure 1100 is a hybrid CFET structure including both a unipolar portion of the CFET structure and a dual polarity portion of the CFET structure. In some embodiments, the CFET structure 1100 is usable to form a portion of the functional circuit 110 (FIG. 1). In some embodiments, the CFET structure 1100 is usable to define a portion of an SRAM.

The CFET structure 1100 includes a first gate structure 1110 usable as part of a pass gate for an SRAM. The CFET structure 1100 further includes a second gate structure 1120 electrically connected to a third gate structure 1130, which are collectively usable as part of an inverter 1140 for the SRAM. In some embodiments, a structure of each of the first gate structure 1110, the second gate structure 1120, and the third gate structure 1130 is similar to the structure of each of the plurality of gate structures 420 (FIG. 4), and are not described in detail for the sake of brevity.

The CFET structure 1100 further includes a plurality of S/D regions 1150. In some embodiments, the S/D regions 1150 are similar to the S/D regions 310 (FIG. 3), the first plurality of S/D regions 410 (FIG. 4), the second plurality of S/D regions 415 (FIG. 4), or the third plurality of S/D regions 435 (FIG. 4), and are not described in detail for the sake of brevity.

The CFET structure 1100 includes a channel region 1160 and a channel region 1170. In some embodiments, the channel region 1160 is similar to the channel region 460 (FIG. 4) and is not described in detail for the sake of brevity. In some embodiments, the channel region 1170 is similar to the channel region 450 (FIG. 4) and is not described in detail for the sake of brevity.

The CFET structure 1100 includes an opening 1180 vertically offset from the first gate structure 1110. The opening 1180 is able to be filled with a dielectric material replacing a gate structure in comparison with a fully dual polarity CFET structure. In some embodiments, the opening 1180 is similar to opening 350 (FIG. 3) and is not described in detail for the sake of brevity.

In comparison with the CFET structure 300 (FIG. 3), the CFET structure 1100 includes a unipolar portion at the first gate structure 1110; and a dual polarity portion at the second gate structure 1120 and the third gate structure 1130. This hybrid structure allows the CFET structure 1100 to have increased utilization for different functionalities in an IC. Instead of an IC design including all unipolar CFET structures or dual polarity CFET structures, components of the CFET structure utilizing different levels of polarity are able to be formed in a single hybrid CFET structure. This helps to reduce the overall size of the IC and reduces complexity of manufacturing the IC by reducing routing complexity.

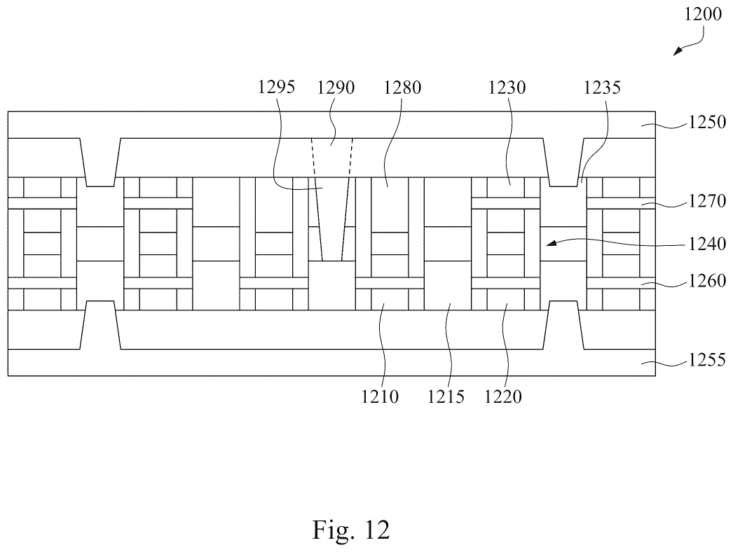

FIG. 12 is a cross-sectional view of a CFET structure 1200, in accordance with some embodiments. The CFET structure 1200 is a hybrid CFET structure. The CFET structure 1200 is a multi-finger device. In some embodiments, components of the CFET structure 1200 are similar to the CFET structure 400 (FIG. 4). Labeling of components, such the MDI layer 480 and the spacers 440 (FIG. 4) and a detailed description of some aspects of the CFET structure 1200 are omitted for the sake of brevity and clarity of the drawing. The CFET structure 1200 includes a symmetrical arrangement where the unipolar portion of the CFET structure 1200 is centrally located with the dual polarity portions of the CFET structure 1200 being on either side of the unipolar portion of the CFET structure 1200. In some embodiments, the CFET structure 1200 includes an asymmetric arrangement where all unipolar components of the CFET structure 1200 are grouped together and all dual polarity components of the CFET structure 1200 are grouped together. For the sake of clarity of the drawing, only half of FIG. 12 includes labels.

The CFET structure 1200 includes a first gate structure 1210 as part of a lower device. In some embodiments, a structure of the first gate structure 1210 is similar to the plurality of gate structures 420 (FIG. 4). The CFET structure 1200 further includes a lower plurality of S/D regions 1215. In some embodiments, a structure of the lower plurality of S/D regions 1215 is similar to the third plurality of S/D regions 435 (FIG. 4). The first gate structure 1210 is vertically offset from a dielectric material 1280. In some embodiments, the dielectric material 1280 is similar to the dielectric material 430 (FIG. 4). The CFET structure 1200 further includes a channel region 1260. In some embodiments, the channel region 1260 is similar to the channel region 460 (FIG. 4). Due to the presence of the dielectric material 1280, the location of the first gate structure 1210 is a unipolar portion of the CFET structure 1200. In some embodiments, the unipolar portion of the CFET structure 1200 is usable as a pass gate for an SRAM. In the CFET structure 1200, the first gate structure 1210 is separated from the dielectric material 1280 by an MDI layer. In some embodiments, the MDI layer is omitted and the dielectric material 1280 directly contacts the first gate structure 1210.

The CFET structure 1200 further includes a second gate structure 1220 as part of the lower device. The CFET structure 1200 further includes a third gate structure 1230 as part of the upper device. In some embodiments, a structure of each of the second gate structure 1220 and the third gate structure 1230 is similar to the plurality of gate structure 420 (FIG. 4). The CFET structure further includes a plurality of upper S/D regions 1235. In some embodiments, a structure of the upper plurality of S/D regions 1235 is similar to the first plurality of S/D regions 410 (FIG. 4) or the second plurality of S/D regions 415 (FIG. 4). The CFET structure 1200 further includes a channel region 1270. In some embodiments, the channel region 1270 is similar to the channel region 450 (FIG. 4). The channel region 1270 is discontinuous within the dielectric material 1280. In the CFET structure 1200, the second gate structure 1220 is separated from the third gate structure 1230 by an MDI layer. In some embodiments, the MDI layer is omitted and the second gate structure 1220 is directly electrically connected to the third gate structure 1230.

The CFET structure 1200 further includes an upper interconnect structure 1250 electrically connected to the upper plurality of S/D regions 1235 in the dual polarity portion of the CFET structure 1200. In some embodiments, the upper interconnect structure 1250 is similar to the top interconnect structure 485 (FIG. 4). The CFET structure 1200 further includes a lower interconnect structure 1255 electrically connected to the lower plurality of S/D regions 1215 in the dual polarity portion of the CFET structure 1200. In some embodiments, the lower interconnect structure 1255 is similar to the bottom interconnect structure 490 (FIG. 4). The CFET structure 1200 further includes a via 1290 electrically connecting the upper interconnect structure 1250 to a through via 1295. The via 1290 is depicted as a dashed outline because the via 1290 is out of the plane of the cross-sectional view of FIG. 12. The CFET structure 1200 further includes the through via 1295 electrically connecting an S/D region 1215 of the lower plurality of S/D regions 1215 in the unipolar portion of the CFET structure 1200 to the upper interconnect structure 1250 through the via 1290. In some embodiments, a structure of each of the via 1290 and the through via 1295 is similar to the through vias 495 (FIG. 4).

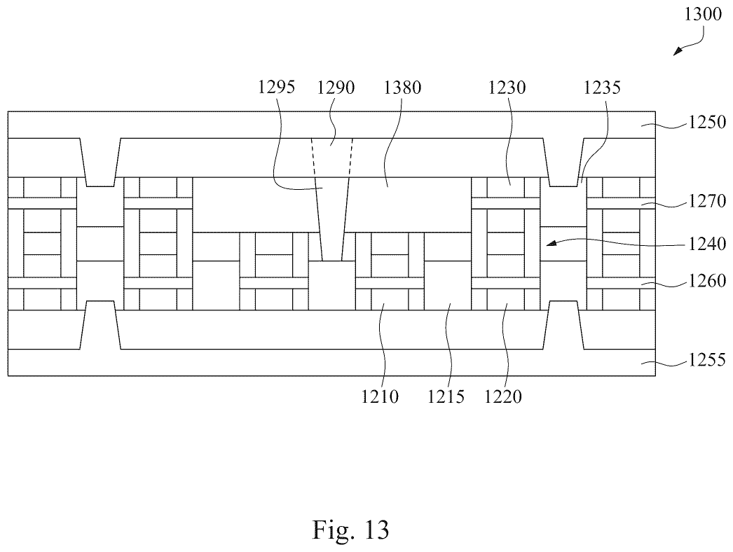

FIG. 13 is a cross-sectional view of a CFET structure 1300, in accordance with some embodiments. The CFET structure 1300 is a hybrid CFET structure. The CFET structure 1300 is a multi-finger device. In some embodiments, the CFET structure 1300 is similar to the CFET structure 1200 (FIG. 12) and similar elements have a same reference number. Labeling of components, such as the MDI layer 480 and spacers 440 (FIG. 4) and a detailed description of some aspects of the CFET structure 1300 is omitted for the sake of brevity and clarity of the drawing. The CFET structure 1300 includes a symmetrical arrangement where the unipolar portion of the CFET structure 1300 is centrally located with the dual polarity portions of the CFET structure 1300 being on either side of the unipolar portion of the CFET structure 1300. In some embodiments, the CFET structure 1300 includes an asymmetric arrangement where all unipolar components of the CFET structure 1300 are grouped together and all dual polarity components of the CFET structure 1300 are grouped together. For the sake of clarity of the drawing, only half of FIG. 13 includes labels.

In comparison with the CFET structure 1200 (FIG. 12), the CFET structure 1300 includes a dielectric material 1380 continuous across the upper device in the unipolar portion of the CFET structure 1300. The dielectric material 1380 extends continuously across the entire unipolar portion of the CFET structure 1300. The components of the upper device are removed using a series of etching processes. In some embodiments, the etching processes remove at least a portion of the spacers along sidewalls of the third gate structure 1230. In some embodiments, the etching processes do not remove the spacers along the sidewalls of the third gate structure 1230. The CFET structure 1300 includes the dielectric material 1380 contacting the MDI layer and the substrate. In some embodiments, the MDI layer and the substrate in the unipolar portion of the CFET structure 1300 are removed and the dielectric material 1380 extends to directly contact the first gate structure 1210 and the lower plurality of S/D regions 1215 in the unipolar portion of the CFET structure 1300. In some embodiments, the dielectric material 1380 includes a similar material as the dielectric material 430 (FIG. 4). In some embodiments, the dielectric material 1380 is formed in a manner similar to the dielectric material 430 (FIG. 4).

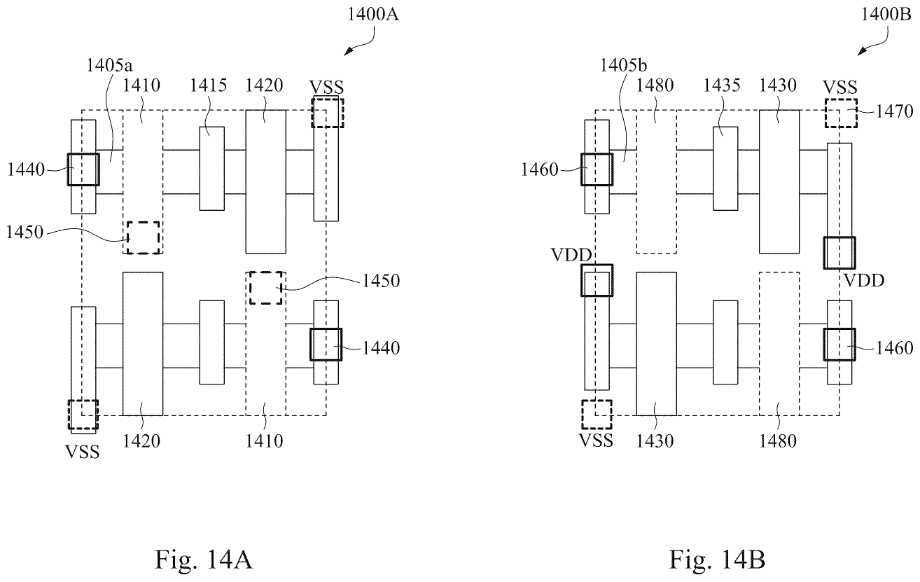

FIG. 14A is a top view of a CFET structure 1400A, in accordance with some embodiments. The CFET structure 1400A is a hybrid CFET structure. In some embodiments, the CFET structure 1400A is usable in an SRAM. The CFET structure 1400A is a top view and includes components of an upper device of the CFET structure, in some embodiments. The CFET structure 1400B (FIG. 14B) is a bottom view and includes components of a lower device of the CFET structure, in some embodiments.

The CFET structure 1400A includes a nanowire 1405a having a first dopant type, e.g., n-type or p-type. The CFET structure 1400A further includes a plurality of first gate structures 1410. In some embodiments, the plurality of first gate structures 1410 have a similar structure as the first gate 1210 (FIG. 12). In some embodiments, the plurality of first gate structures 1410 are usable as a multi-finger pass gate for an SRAM. The CFET structure 1400A includes a plurality of second gate structures 1420. In some embodiments, the plurality of second gate structures 1420 have a similar structure as the third gate 1230 (FIG. 12). In some embodiments, the plurality of second gate structures 1420 are usable as a multi-finger pulldown transistor in an SRAM. The CFET structure 1400A further includes a plurality of S/D regions 1415. In some embodiments, the plurality of S/D regions 1415 have a same structure as the upper plurality of S/D regions 1235 (FIG. 12).

A peripheral S/D region of the plurality of S/D regions 1415 is electrically connected to a ground voltage VSS. The CFET structure 1400A further includes a via 1440 for electrically connecting several S/D regions 1415 of the plurality of S/D regions 1415 to a bit line (BL) of the SRAM. The CFET structure 1400A further includes vias 1450 for electrically connecting each of the plurality of first gate structures to an upper interconnect structure (not shown), for selectively activating the pass gate of the SRAM.

FIG. 14B is a bottom view of a CFET structure, in accordance with some embodiments. The CFET structure 1400B is a hybrid CFET structure. In some embodiments, the CFET structure 1400B is usable in an SRAM. The CFET structure 1400B is a bottom view and includes components of a lower device of the CFET structure, in some embodiments. The CFET structure 1400A (FIG. 14A) is a top view and includes components of an upper device of the CFET structure, in some embodiments.

The CFET structure 1400B includes a nanowire 1405b having a second dopant type, e.g., n-type or p-type. The dopant type of the nanowire 1405b is opposite to the dopant type of the nanowire 1405a (FIG. 14A). The CFET structure 1400B further includes a plurality of regions of dielectric material 1480. In some embodiments, the plurality of regions of dielectric material 1480 have a similar structure as the dielectric material 1280 (FIG. 12). The plurality of regions of dielectric material 1480 in aligned with the plurality of gate structures 1410 (FIG. 14A). The CFET structure 1400B includes a plurality of third gate structures 1430. The third plurality of gate structures 1430 are aligned with the second plurality of gate structures 1420 (FIG. 14A). In some embodiments, the plurality of third gate structures 1430 have a similar structure as the second gate 1220 (FIG. 12). In some embodiments, the plurality of third gate structures 140 are usable as a multi-finger pullup transistor in an SRAM. The CFET structure 1400B further includes a plurality of S/D regions 1435. In some embodiments, the plurality of S/D regions 1435 have a same structure as the lower plurality of S/D regions 1215 (FIG. 12).

A peripheral S/D region of the plurality of S/D regions 1435 is electrically connected to a supply voltage VDD. A through via 1470 electrically connects the ground voltage VSS to the peripheral S/D regions 1415 of the plurality of S/D regions 1415 (FIG. 14A). The CFET structure 1400B further includes a via 1460 for electrically connecting several S/D regions 1435 of the plurality of S/D regions 1435 to a bit line (BL) of the SRAM.

One of ordinary skill in the art would understand that CFET structure 1400A (FIG. 14A) and CFET structure 1400B (FIG. 14B) are part of a single structure, in some embodiments. The combined CFET structure of the CFET structure 1400A and the CFET structure 1400B had a unipolar CFET structure where the first plurality of gate structures 1410 and plurality of regions of dielectric material 1480 are located. The combined CFET structure of the CFET structure 1400A and the CFET structure 1400B had a dual polarity region where the second plurality of gate structures 1420 and the third plurality of gate structures 1430 are located.

Aspects of this description relate to a semiconductor device structure. The semiconductor device includes a first plurality of source/drain (S/D) regions configured to receive an input signal. The semiconductor device further includes a second plurality of S/D regions configured to output an output signal. The semiconductor device further includes a plurality of gate structures, each gate structure of the plurality of gate structures being between a corresponding S/D region of the first plurality of S/D regions and a corresponding S/D region of the second plurality of S/D regions, wherein each of the plurality of gate structures has a same dopant type. The semiconductor device further includes a dielectric material offset from each of the plurality of gate structures. The semiconductor device further includes a through via electrically connected to an S/D region of the second plurality of S/D regions, the through via extending through a substrate. In some embodiments, the semiconductor device structure further includes spacers along sidewalls of each of the plurality of gate structures, wherein the spacers extend continuously along sidewalls of the dielectric material. In some embodiments, the semiconductor device structure further includes a middle dielectric isolation (MDI) layer between the plurality of gate structures and the dielectric material. In some embodiments, the MDI layer comprises a different composition from the dielectric material. In some embodiments, the semiconductor device structure further includes a top interconnect structure configured to convey the input signal to the first plurality of S/D regions and a bottom interconnect structure configured to receive the output signal from the second plurality of S/D regions. In some embodiments, the semiconductor device structure further includes a third plurality of S/D regions offset from the first plurality of S/D regions and the second plurality of S/D regions, wherein the through via extends through a corresponding S/D region of the third plurality of S/D regions. In some embodiments, the dielectric material comprises silicon oxide, silicon nitride, silicon oxynitride, silicon carbide, silicon oxycarbide, or a combination thereof. In some embodiments, each gate structure of the plurality of gate structures comprises a metal layer and a high-k dielectric layer, the high-k dielectric layer being between the metal layer and a channel region.

Aspects of this description relate to an integrated circuit. The integrated circuit includes a functional circuit. The integrated circuit further includes a power gating structure configured to selectively electrically separate the functional circuit from a supply voltage. The power gating structure includes a unipolar complementary field effect transistor (CFET) structure, wherein the unipolar CFET structure includes a functional device having a single dopant type; and a dielectric material at a location of a device having a dopant type opposite the single dopant type. In some embodiments, the power gating structure comprises a power gating header configured to receive the supply voltage. In some embodiments, the power gating structure comprises a power gating footer electrically between the functional circuit and a ground voltage. In some embodiments, the functional circuit comprises a static random access memory (SRAM) cell. In some embodiments, the unipolar CFET structure comprises an upper device having gate structures of the single dopant type and a lower device having the dielectric material at locations corresponding to the gate structures of a dopant type opposite to the single dopant type. In some embodiments, the integrated circuit further includes continuous poly on oxide definition edge (CPODE) structures on opposing ends of the unipolar CFET structure.

Aspects of this description relate to a method of making a semiconductor device structure. The method includes forming a dual polarity complementary field effect transistor (CFET) structure comprising an upper device and a lower device, the lower device comprising a gate structure. The method further includes removing the gate structure of the lower device to define an opening. The method further includes depositing a dielectric material into the opening. The method further includes planarizing the dielectric material. The method further includes forming a through via extending through a substrate to electrically connect to a source/drain (S/D) region of the upper device. In some embodiments, removing the gate structure of the lower device comprises a series of photolithography and etching processes. In some embodiments, depositing the dielectric material comprises chemical vapor deposition (CVD) or atomic layer deposition (ALD). In some embodiments, the method further includes using a mask to remove the gate structure; and removing the mask from the lower device before depositing the dielectric material. In some embodiments, removing the gate structure of the lower device further removes a portion of spacers on sidewalls of the gate structure of the lower device. In some embodiments, the method further includes forming a bottom interconnect structure electrically connected to the through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure comprising:
a first plurality of source/drain (S/D) regions configured to receive an input signal;
a second plurality of S/D regions configured to output an output signal;
a plurality of gate structures, each gate structure of the plurality of gate structures being between a corresponding S/D region of the first plurality of S/D regions and a corresponding S/D region of the second plurality of S/D regions, wherein each of the plurality of gate structures has a same dopant type;
a dielectric material offset from each of the plurality of gate structures; and
a through via electrically connected to an S/D region of the second plurality of S/D regions, the through via extending through a substrate.

2. The semiconductor device structure of claim 1, further comprising spacers along sidewalls of each of the plurality of gate structures, wherein the spacers extend continuously along sidewalls of the dielectric material.

3. The semiconductor device structure of claim 1, further comprising a middle dielectric isolation (MDI) layer between the plurality of gate structures and the dielectric material.

4. The semiconductor device structure of claim 3, wherein the MDI layer comprises a different composition from the dielectric material.

5. The semiconductor device structure of claim 1, further comprising a top interconnect structure configured to convey the input signal to the first plurality of S/D regions and a bottom interconnect structure configured to receive the output signal from the second plurality of S/D regions.

6. The semiconductor device structure of claim 1, further comprising a third plurality of S/D regions offset from the first plurality of S/D regions and the second plurality of S/D regions, wherein the through via extends through a corresponding S/D region of the third plurality of S/D regions.

7. The semiconductor device structure of claim 1, wherein the dielectric material comprises silicon oxide, silicon nitride, silicon oxynitride, silicon carbide, silicon oxycarbide, or a combination thereof.

8. The semiconductor device structure of claim 1, wherein each gate structure of the plurality of gate structures comprises a metal layer and a high-k dielectric layer, the high-k dielectric layer being between the metal layer and a channel region.

9. An integrated circuit comprising:
a functional circuit; and
a power gating structure configured to selectively electrically separate the functional circuit from a supply voltage, the power gating structure comprising:
a unipolar complementary field effect transistor (CFET) structure, wherein the unipolar CFET structure comprises:
a functional device having a single dopant type; and
a dielectric material at a location of a device having a dopant type opposite the single dopant type.

10. The integrated circuit of claim 9, wherein the power gating structure comprises a power gating header configured to receive the supply voltage.

11. The integrated circuit of claim 9, wherein the power gating structure comprises a power gating footer electrically between the functional circuit and a ground voltage.

12. The integrated circuit of claim 9, wherein the functional circuit comprises a static random access memory (SRAM) cell.

13. The integrated circuit of claim 9, wherein the unipolar CFET structure comprises an upper device having gate structures of the single dopant type and a lower device having the dielectric material at locations corresponding to the gate structures of a dopant type opposite to the single dopant type.

14. The integrated circuit of claim 9, further comprising continuous poly on oxide definition edge (CPODE) structures on opposing ends of the unipolar CFET structure.

15. A method of making a semiconductor device structure, the method comprising:
forming a dual polarity complementary field effect transistor (CFET) structure comprising an upper device and a lower device, the lower device comprising a gate structure;
removing the gate structure of the lower device to define an opening;
depositing a dielectric material into the opening;
planarizing the dielectric material; and
forming a through via extending through a substrate to electrically connect to a source/drain (S/D) region of the upper device.

16. The method of claim 15, wherein removing the gate structure of the lower device comprises a series of photolithography and etching processes.

17. The method of claim 15, wherein depositing the dielectric material comprises chemical vapor deposition (CVD) or atomic layer deposition (ALD).

18. The method of claim 15, further comprising:
using a mask to remove the gate structure; and
removing the mask from the lower device before depositing the dielectric material.

19. The method of claim 15, wherein removing the gate structure of the lower device further removes a portion of spacers on sidewalls of the gate structure of the lower device.

20. The method of claim 15, further comprising forming a bottom interconnect structure electrically connected to the through via.
